(19) United States
(12) Patent Application Publication
(10) Pub. No.: US 2009/0042390 A1
(43) Pub. Date: Feb. 12, 2009

(54) ETCHANT FOR SILICON WAFER SURFACE SHAPE CONTROL AND METHOD FOR MANUFACTURING SILICON WAFERS USING THE SAME

(76) Inventors: Sakae Koyata, Tokyo (JP); Takeo Katoh, Tokyo (JP); Tomohiro Hashii, Tokyo (JP); Katsuhiko Murayama, Tokyo (JP); Kazushige Takaishi, Tokyo (JP)

Correspondence Address: DUANE MORRIS LLP - NY;PATENT DEPARTMENT, 1540 BROADWAY, NEW YORK, NY, 10036-4086, US

(21) Appl. No.: 11/836,493

(22) Filed: Aug. 9, 2007

(51) Int. Cl. H01L 21/302; C09K 13/08

(52) U.S. Cl. 438/691; 252/79.3; 257/E21.214

(57) ABSTRACT

It is possible to reduce workloads of a both-side simultaneous polishing process or a single-side polishing process, and to achieve both of the maintenance of the wafer flatness and the reduction in wafer front side roughness upon completing a flattening process. A method for manufacturing silicon wafers according to the present invention includes a flattening process 13 of grinding or lapping front and back sides of a thin disc-shaped silicon wafer obtained by slicing a silicon single crystal ingot, an etching process of immersing the silicon wafer in an etchant for controlling a silicon wafer surface shape in which a fluorochemical surfactant is uniformly mixed in an alkaline aqueous solution to etch the front and back sides of the silicon wafer, and a both-side simultaneous polishing process 16 of simultaneously polishing the front and back sides of the etched silicon wafer or a single-side polishing process of polishing the front and back sides of the etched wafer for every side, in this order.

### BACKGROUND OF THE INVENTION

1. Field of the Invention

The present invention relates to an etchant for controlling a silicon wafer surface shape and a method for manufacturing silicon wafers using the etchant, which are capable of reducing workloads of a both-side simultaneous polishing process, and achieving both of the high flatness and the reduction in front side roughness.

2. Description of the Related Art

Generally, a manufacturing process of semiconductor silicon wafers is composed of processes of chamfering, mechanically polishing (lapping), etching, mirror-polishing (polishing) and cleaning wafers obtained by cutting and slicing a pulled silicon single crystal ingot, and produces wafers having highly precise flatness. The silicon wafers, which have passed through mechanical manufacturing processes, such as block cutting, outer diameter grinding, slicing, and lapping, have damaged layers, namely, work-affected layers, on the surface thereof. Since the work-affected layer causes crystal defects, such as a slip dislocation or the like during device manufacturing processes, reduces mechanical strength of the wafer and adversely influences on electrical characteristics thereof, it must be completely removed.

An etching process is performed in order to remove the work-affected layer. Either of an acid etching method and an alkali etching method is employed for the etching process. In this etching process, the work-affected layer is chemically removed by immersing a plurality of wafers in an etching bath that containing the etchant.

The acid etching has advantages that there is no selective etching characteristic to the silicon wafer, micro shape-precision is improved because of a small front side roughness, and etching efficiency is high. An etchant due to three components in which mixed acid of hydrofluoric acid (HF) and nitric acid (HNO₃) is diluted with water (H₂O) or acetic acid (CH₃COOH) is mainly used for the etchant of this acid etching. It is considered that the reason why the above-mentioned advantages are obtained by the acid etching is that etching progresses on based on diffusion-controlled conditions by the above-mentioned etchant, and reaction velocity does not depend on a plane orientation of a crystal front side, a crystal defect, or the like under these diffusion-controlled conditions, but diffusion on the crystal front side has a major effect. In this acid etching, however, although the work-affected layer can be etched while improving the front side roughness of the silicon wafer, an outer circumferential portion of the wafer becomes dull as the acid etching progresses on, and the flatness which is a macroscopic shape precision obtained by the lapping is impaired, causing problems that unevenness called waves or peels in a range of mm order on an etched surface. Further, there have been disadvantages that a cost of a chemical liquid is high, and in addition to that, it is difficult to control and maintain the composition of the etchant.

The alkali etching has features that the flatness is superior and the macroscopic shape precision is improved, and metallic contamination is low, and there is no problem of harmful by-products such as NOₓ in the acid etching and no danger in handling thereof. KOH and NaOH are used as the etchant of this alkali etching. It is considered that the reason why the above-mentioned features are obtained by the alkali etching is that this etching basically progresses on based on conditions of surface diffusion control. In the alkali etching, however, although the work-affected layer can be etched while maintaining the flatness of the silicon wafer, pits (Hereinafter, these are called facets.) with a partial depth of several micrometers and a size of about several to several tens of micrometers are generated, causing problems that the wafer front side roughness is deteriorated.

As measures for solving the above-mentioned problems in the alkali etching, there is disclosed an etching method for silicon wafers using an etchant in which hydrogen peroxide of 0.01-0.2 weight percent is added to caustic soda (sodium hydroxide) aqueous solution of 100 weight percent (For example, refer to Patent Document 1.). According to the etching method disclosed in the above-mentioned Patent Document 1, it is described that problems caused in the alkali etching due to a caustic soda aqueous solution is solved by adding hydrogen peroxide to the caustic soda aqueous solution at a predetermined ratio. Specifically, the size of the etch pit on the backside of the silicon wafer is made finer as compared with etching using an NaOH aqueous solution, generation of micro etch pits on the backside of the silicon wafer is also suppressed, and a desired etching rate can be adjusted easily and in a wide extent, thereby resulting in an increase in etching rate.

[Patent Document 1]

Japanese Unexamined Patent Publication (Kokai) No. H7-37871 (claims 1 through 4, paragraph [0021])

In the conventional methods including the method shown in the above-mentioned Patent Document 1, however, although the etched wafer is subjected to a both-side simultaneous polishing process or a single-side polishing process to thereby make the front side thereof into a mirror plane the wafer flatness upon completing a flattening process cannot be maintained and the desired wafer front side roughness is not obtained, either, on front and back sides of a silicon wafer which has been subjected to an etching process, and thus in order to improve the wafer flatness and the wafer front side roughness, it is necessary to take large polishing removal allowances in the both-side simultaneous polishing process or the single-side polishing process, thereby high workload has been imposed on the both-side simultaneous polishing process or the single-side polishing process.

### SUMMARY OF THE INVENTION

It is an object of the present invention to provide an etchant for controlling a silicon wafer surface shape and a method for manufacturing the silicon wafers using the etchant, which are capable of reducing workloads of a both-side simultaneous polishing process and a single-side polishing process, and achieving both of the maintenance of the wafer flatness and the reduction in wafer front side roughness upon completing a flattening process.

The invention in accordance with claim 1 is an etchant for controlling a silicon wafer surface shape, wherein a fluorochemical surfactant is uniformly mixed in an alkaline aqueous solution.

In the invention in accordance with claim 1, since the etchant in which the fluorochemical surfactant is mixed uniformly in the alkaline aqueous solution can control the front side roughness and the texture size of the wafer before polishing, etching the silicon wafer with an work-affected layer, to which a flattening process has been subjected, using this etchant makes it possible to achieve both the maintenance of the wafer flatness and the reduction in wafer front side roughness upon completing the flattening process while reducing the polishing removal allowances on front and back sides of the wafer in a both-side simultaneous polishing process or a single-side polishing process, respectively.

The invention according to claim 2 is the etchant in accordance with claim 1, wherein the alkaline aqueous solution is a sodium hydroxide aqueous solution of 20-50 weight percent, and an addition ratio of the fluorochemical surfactant to be added to the alkaline aqueous solution is 0.0015-15 g/L to sodium hydroxide.

In the invention in accordance with claim 2, adding the fluorochemical surfactant to the sodium hydroxide aqueous solution with the above-mentioned concentration range at a predetermined ratio makes it possible to further reduce the front side roughness and the flatness of the wafer to which the etching process has been subjected.

The invention in accordance with claim 3 is a method for manufacturing silicon wafers as shown in FIG. 1, sequentially including a flattening process 13 for grinding or lapping front and back sides of a thin disc-shaped silicon wafer obtained by slicing a silicon single crystal ingot, an etching process 14 of immersing the silicon wafer in an etchant obtained by mixing a fluorochemical surfactant uniformly in an alkaline aqueous solution to thereby etch the front and back sides of the silicon wafer, and a both-side simultaneous polishing process 16 of simultaneously polishing the front and back sides of the etched silicon wafer.

In the invention in accordance with claim 3, since the front side roughness and the texture size of the wafer before polishing can be controlled by the etching process 14 using the adjusted etchant in which the fluorochemical surfactant is added to the alkaline aqueous solution, it is possible to achieve both of the maintenance of the wafer flatness and the reduction in wafer front side roughness upon completing the flattening process while reducing the polishing removal allowances on the front and back sides of the wafer in the both-side simultaneous polishing process 16, respectively.

The invention according to claim 4 is the method in accordance with claim 3, wherein the alkaline aqueous solution is a sodium hydroxide aqueous solution of 20-50 weight percent, and an addition ratio of the fluorochemical surfactant to be added to the alkaline aqueous solution is 0.0015-15 g/L to sodium hydroxide.

The invention in accordance with claim 5 is a method for manufacturing silicon wafers, sequentially including a flattening process of grinding or lapping front and back sides of a thin disc-shaped silicon wafer obtained by slicing a silicon single crystal ingot, an etching process of immersing the silicon wafer in an etchant obtained by mixing a fluorochemical surfactant uniformly in an alkaline aqueous solution to thereby etch the front and back sides of the silicon wafer, and a single-side polishing process of polishing the front and back sides of the etched silicon wafer for every side.

In the invention in accordance with claim 5, since the front side roughness and the texture size of the wafer before polishing can be controlled by the etching process using the adjusted etchant in which the fluorochemical surfactant is added to the alkaline aqueous solution, it is possible to achieve both of the maintenance of the wafer flatness and the reduction in wafer front side roughness upon completing the flattening process while reducing the polishing removal allowances on the front and back sides of the wafer in the single-side polishing process, respectively.

The invention according to claim 6 is the method in accordance with claim 5, wherein the alkaline aqueous solution is a sodium hydroxide aqueous solution of 20-50 weight percent, and an addition ratio of the fluorochemical surfactant to be added to the alkaline aqueous solution is 0.0015-15 g/L to sodium hydroxide.

### ADVANTAGEOUS EFFECT OF THE INVENTION

The etchant for controlling a silicon wafer surface shape of the present invention is an etchant in which the fluorochemical surfactant is uniformly mixed in the alkaline aqueous solution, and this etchant can control the front side roughness and the texture size of the wafer before polishing, so that etching the silicon wafer with the work-affected layer, to which the flattening process has been subjected, using this etchant, makes it possible to achieve both of the maintenance of the wafer flatness and the reduction in wafer front side roughness upon completing the flattening process while reducing the polishing removal allowances on the front and back sides of the wafer in a both-side simultaneous polishing process or a single-side polishing process, respectively.

Moreover, in the method for manufacturing the silicon wafers according to the present invention, since the front side roughness and the texture size of the wafer before polishing can be controlled by the etching process using the adjusted etchant in which the fluorochemical surfactant is added to the alkaline aqueous solution, it is possible to achieve both of the maintenance of the wafer flatness and the reduction in wafer front side roughness upon completing the flattening process while reducing polishing removal allowances on the front and back sides of the wafer in a both-side simultaneous polishing process or a single-side polishing process, respectively.

### BRIEF DESCRIPTION OF THE DRAWINGS

FIG. 1 is a process chart showing a method for manufacturing silicon wafers according to the present invention;

FIG. 2 is a plan view showing a grinding apparatus;

FIG. 3 is a longitudinal sectional view showing the grinding apparatus;

FIG. 4 is a block diagram showing a lapping apparatus;

FIG. 5 is a diagram showing an etching processing process;

FIG. 6 is a block diagram showing a both-side simultaneous polishing apparatus;

FIG. 7 is a wafer sectional view for explaining how to calculate Ra; and

FIG. 8 is a wafer sectional view for explaining how to calculate Rmax.

### DETAILED DESCRIPTION OF THE PREFERRED EMBODIMENTS

Next, the best mode for carrying out the present invention will be described based on the drawings.

An etchant for controlling a silicon wafer surface shape of the present invention is an etchant in which a fluorochemical surfactant is uniformly mixed in an alkaline aqueous solution. This etchant in which the fluorochemical surfactant is uniformly mixed in this alkaline aqueous solution acts on metal impurities or the like in a chemical liquid by adding the fluorochemical surfactant thereto and suppresses selectivity peculiar to an alkali etching, thereby can control the front side roughness and the texture size of the wafer before polishing, and thus etching the silicon wafer with the work-affected layer, to which the flattening process has been subjected, using this etchant, makes it possible to achieve both of the maintenance of the wafer flatness and the reduction in wafer front side roughness upon completing the flattening process while reducing the polishing removal allowances on front and back sides of the wafer in a both-side simultaneous polishing process or a single-side polishing process, respectively.

The etchant of the present invention is obtained by adding the fluorochemical surfactant to the alkaline aqueous solution adjusted to a predetermined concentration at a predetermined ratio, stirring this added liquid, and mixing the fluorochemical surfactant uniformly in the alkaline aqueous solution. While potassium hydroxide and sodium hydroxide are listed as the alkaline aqueous solution included in the etchant of the present invention, especially among them, a sodium hydroxide aqueous solution in which sodium hydroxide concentration is 20-50 weight percent, preferably 40-50 weight percent is superior in reduction of front side roughness and suppression of texture size of the wafer before polishing. Moreover, it is preferable that an addition ratio of the fluorochemical surfactant to be added to this sodium hydroxide aqueous solution of 20-50 weight percent is in a range of 0.0015-15 g/L to the sodium hydroxide since the wafer front side roughness and the wafer flatness after an etching process can be further reduced. Particularly, it is preferable that the addition ratio is in a range of 0.15-1.5 g/L to the sodium hydroxide. The fluorochemical surfactant used for the etchant of the present invention includes 1,1,2,2,3,3,4,4,5,5,6,6,7,7,8,8,8-pentadecafluoro-1-octanesulfonic acid (C₈F₁₇SO₃H), Potassium perfluoro octanesulfonate (C₈F₁₇SO₃K) Sodium perfluoro octanesulfonate (C₈F₁₇SO₃Na) Ammonium perfluoro octanesulfonate (C₈F₁₇SO₃NH₄), Lithium perfluoro octanesulfonate (C₈F₁₇SO₃Li) Potassium N-[(perfluorooctyl) sulfonyl]-N-propylglycinate (C₈F₁₇SO₂N(C₃H₇)CH₂COOK), N-(2-hydroxylethyl)-N-propyl perfluorooctane sulfonamide (C₈F₁₇SO₂N(C₃H₇)CH₂CH₂OH), N-polyoxyethylene-N-propyl perfluorooctane sulfonamide (C₈F₁₇SO₂N(C₃H₇) (C₂H₄O)ₙH; n=3, 10, 20), Phosphorous acid ester ([C₈F₁₇SO₂N(C₃H₇) (C₂H₄O)]₂PO(OH)), Phosphorous acid ester ammonium salt ([C₈F₁₇SO₂N(C₃H₇) (C₂H₄O)]₂PO(ONH₄)), N-[3-(perfluorooctanesulfonamide)propyl]-N,N,N-trimethylammonium iodide (C₈F₁₇SO₂NHCH₂CH₂CH₂N+(CH₃)₃I⁻), copolymer of acrylicacidpolyoxyalkylene (C₂₋₃) alkyl etherandacrylic acid N-perfluoro octyl sulformyl-N-alkyl amino ethyl, copolymer of acrylic acid polyoxyalkylene glycolmonoester acrylic acid N-perfluoro octyl sulformyl-N-alkyl amino ethyl, copolymer of acrylic acid polyoxyethylene alkyl ether and acrylic acid N-perfluoro octyl sulformyl-N-alkyl aminoethyl (50% ethyl acetate), Copolymer of acrylic acid polyoxyalkylene alkyl ether acrylic acid N-perfluoro octyl sulformyl-N-alkyl amino ethyl (50% ethyl acetate), copolymer of acrylic acid polyoxyalkylene glycolmonoester and acrylic acid N-perfluoro octyl sulformyl-N-alkyl amino ethyl, Pentadecafluorooctanoic acid (C₇F₁₅COOH), Pentadecafluorooctanoic acid ammonium (C₇F₁₅COONH₄), Perfluoro butanesulfonate (C₄F₉SO₃H), Potassium perfluoro butanesulfonate (C₄F₉SO₃K), Lithium perfluoro butanesulfonate (C₄F₉SO₃Li), or the like. Especially, C₈F₁₇SO₃K and C₈F₁₇SO₃Na are preferable since they exhibit effects to act during reaction with the silicon interface in the alkali etching to thereby weaken selectivity peculiar to the alkali etching.

Next, a manufacturing method of the silicon wafer using the etchant for controlling the silicon wafer surface shape of the present invention will be described.

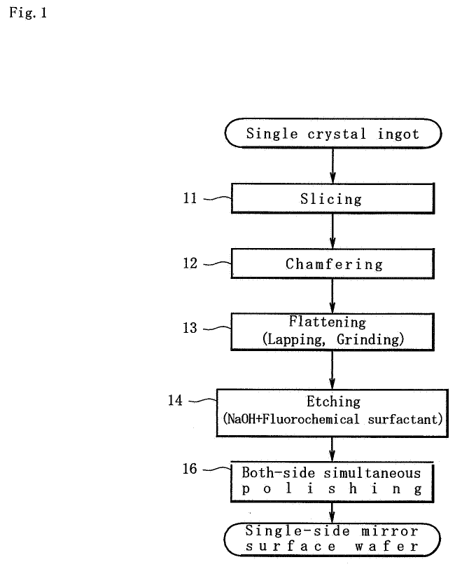

First, a grown silicon single crystal ingot is made into a block shape by cutting a top portion and a bottom portion thereof, and in order to make a diameter of the ingot uniform, the outside diameter of the ingot is ground to be made into a block body. In order to indicate a specific crystal orientation, orientation flats and orientation notches are formed in this block body. After this process, the block body is sliced with a predetermined angle to a direction of a rod axis as shown in FIG. 1 (step 11). In order to prevent cracks and chips around the periphery of the wafer, the periphery of the wafer sliced at process 11 is subjected to a chamfering process (step 12). For example a crown phenomenon, in which an erroneous growth occurs in the periphery of the wafer when the epitaxial growth is made on the front side of the silicon wafer which has not been chamfered and rises annularly, can be suppressed by performing this chamfering process.

Subsequently, uneven layers on the front and back sides of the thin disc-shaped silicon wafer caused at the slicing process or the like are flattened to increase the flatness of the front and back sides of the wafer and the parallel accuracy of the wafer (step 13). In this flattening process 13, the front and back sides of the wafer are flattened by grinding or lapping.

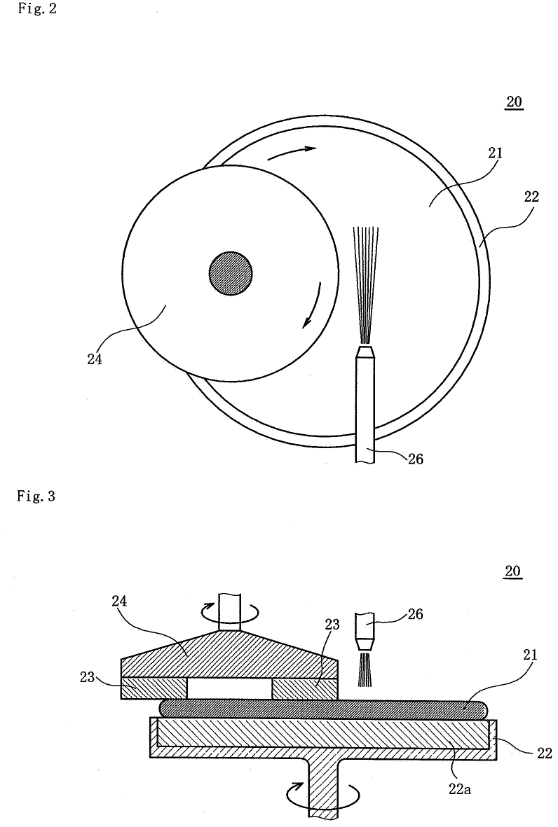

A method for flattening the wafer by grinding is carried out by a grinding apparatus 20 as shown in FIG. 2 and FIG. 3. As shown in FIG. 2, a turntable 22, which is a processed body-supporting member for mounting a silicon wafer 21, is rotatably constituted around a vertical axis by a drive mechanism, which is not shown. As shown in FIG. 3, a grinding stone supporting means 24 for supporting a grinding stone 23 for grinding is provided in an upper side of the turntable 22 to the silicon wafer 21 which is adsorbed and mounted on the turntable 22 through a chuck 22a so as to press a grinding surface thereof. This grinding stone supporting means 24 is constituted so as to allow the grinding stone 23 for grinding to rotate around the vertical axis by the drive mechanism, which is not shown. A water supply nozzle 26 for supplying grinding water on the front side of the silicon wafer 21 during grinding is also provided in the upper part of the silicon wafer. In such the grinding apparatus 20, the grinding stone 23 for grinding and the silicon wafer 21 are relatively rotated by respective drive mechanisms, the grinding water is further supplied from the water supply nozzle 26 to a part different from a contact part with the grinding stone 23 for grinding on the front side of the silicon wafer 21, the front side of the silicon wafer 21 is ground so as to press the grinding stone 23 for grinding thereon while cleaning the front side of the silicon wafer 21.

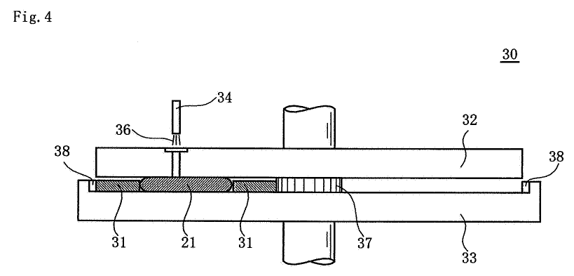

In addition, a method for flattening the wafer by lapping is carried out by a lapping apparatus 30 as shown in FIG. 4. First, a carrier plate 31 is engaged to a sun gear 37 and an internal gear 38 of a lapping apparatus 30, and the silicon wafer 21 is set within a holder of the carrier plate 31 as shown in FIG. 4. Thereafter, both sides of this silicon wafer 21 are held by an upper surface table 32 and a lower surface table 33 so as to be disposed therebetween, the carrier plate 31 is exercised the sun-and-planet motion by the sun gear 37 and the internal gear 38 while supplying an abrasive material 36 from the nozzle 34, and the upper surface table 32 and the lower surface table 33 are simultaneously rotated in a relative direction, thereby both sides of the silicon wafer 21 are simultaneously lapped. Thus, the silicon wafer to which the flattening process 13 is subjected is increased in flatness of the front and backsides of the wafer and parallel accuracy of the wafer, and is cleaned at a cleaning process to be sent to a next process.

Next, returning to FIG. 1, the flattened silicon wafer is immersed in an etchant to etch the front and backsides of the silicon wafer (step 14). The etchant used here is the etchant for controlling a silicon wafer surface shape of the above-mentioned present invention. At this etching process 14, the work-affected layer which is introduced by a mechanical manufacturing process such as the chamfering process 12 or the flattening process 13 is completely removed by etching. Since etching using the etchant for surface shape control of the present invention which is adjusted by adding a silica powder makes it possible to control the front side roughness and the texture size of the wafer, it is possible to achieve both of the maintenance of the wafer flatness and the reduction in wafer front side roughness upon completing the flattening process while reducing the polishing removal allowances in the front and back sides of the wafer at the following both-side simultaneous polishing process 16 and single-side polishing process, respectively. Preferably, an etching removal allowance in the etching process 14 is 8 to 10 micrometers, and the total allowance of the front and backsides of the wafer is 16 to 20 micrometers. Setting the etching removal allowance to the aforementioned range makes it possible to significantly reduce the polishing removal allowances in the following both-side simultaneous polishing process and single-side polishing process. When the etching removal allowance is in less than a lower limit, the wafer front side roughness is not sufficiently reduced, resulting in an increase in the workload of both-side simultaneous polishing or single-side polishing, whereas when it exceeds upper limit, the wafer flatness is impaired, resulting in a deterioration in productivity in wafer manufacturing.

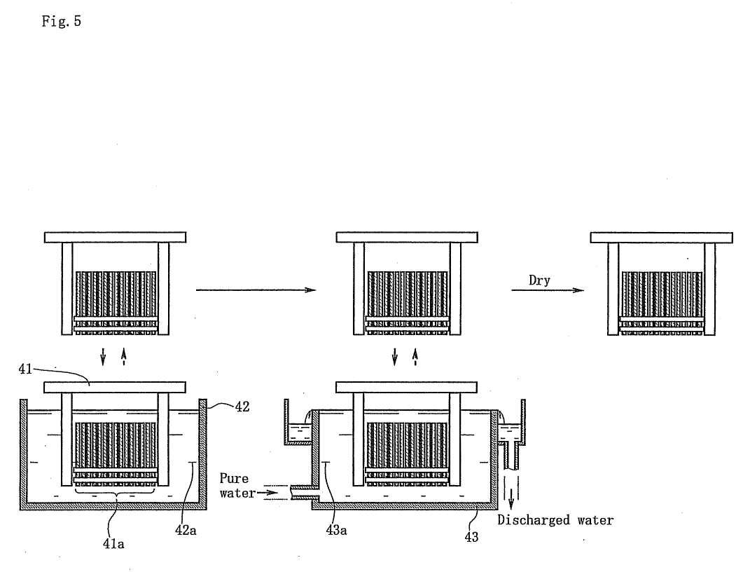

In this etching process 14, as shown in FIG. 5, first, a plurality of wafers 41a are perpendicularly held in a holder 41, this holder 41 is then descended as the solid line arrow in FIG. 5 indicates to be immersed into an etchant 42a for surface shape control of the present invention contained in an etching bath 42, and the work-affected layer on the wafer surface is removed with the etchant. Subsequently, the holder 41 holding the wafers 41a which have been immersed in the etchant 42a for a predetermined time is pulled up as the dashed-line arrow in FIG. 5 indicates. Next, the holder 41 holding the wafers 41a, which have been subjected to the etching process, is descended as the solid line arrow in FIG. 5 indicates to be immersed into a rinsing solution 43a, such as pure water, contained in a rinse tub 43, and the etchant adhering to the wafer surface is removed. Subsequently, the holder 41 holding the wafers 41a, which have been immersed in the rinsing solution 43a for a predetermined time, is pulled up as the dashed-line arrow in FIG. 5 indicates to dry the silicon wafers.

Next, returning to FIG. 1, both-side simultaneous polishing for simultaneously polishing the front and backsides of the wafer after the etching process 14 is subjected thereto (step 16).

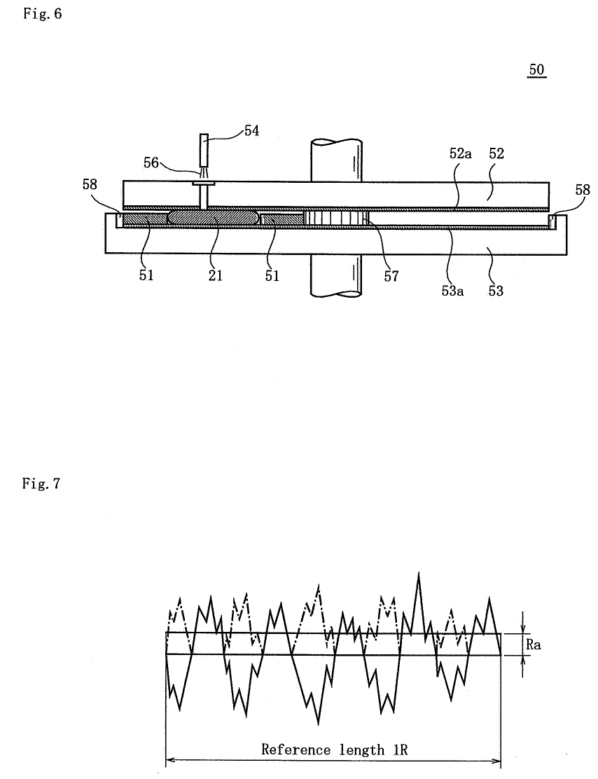

A method of performing the both-side simultaneous polishing is carried out by a both-side simultaneous polishing apparatus 50 as shown in FIG. 6. As shown in FIG. 6, first, a carrier plate 51 is engaged to a sun gear 57 and an internal gear 58 of the both-side simultaneous polishing apparatus 50, and the silicon wafer 21 is set within a holder of the carrier plate 51. Thereafter, both sides of this silicon wafer 21 are held by an upper surface table 52 in which a first abrasive cloth 52a is pasted on a polishing surface side, and a lower surface table 53 in which a second abrasive cloth 53a was pasted on a polishing surface side so as to be disposed therebetween, the carrier plate 51 is exercised the sun-and-planet motion by the sun gear 57 and the internal gear 58 while supplying an abrasive material 56 from a nozzle 54, the upper surface table 52 and the lower surface table 53 are simultaneously rotated in a relative direction, thereby both sides of the silicon wafer 21 are simultaneously mirror-polished. Moreover, in this both-side simultaneous polishing process 16, it is possible to obtain a single-side mirror surface wafer in which the front and back sides of the wafer can be visually identified by simultaneously grinding the front and back sides of the silicon wafer while controlling rotational frequencies of the upper surface table 52 and the lower surface table 53, respectively. As described above, productivity in wafer manufacturing is significantly improved by carrying out the manufacturing method of the silicon wafer of the present invention.

Incidentally, although the front and back sides of the wafer have been simultaneously polished by the both-side simultaneous polishing in this embodiments, it will be obvious that a similar effect may be obtained even when the wafer is polished by the single-side polishing in which the front and back sides of the wafer are polished for every side instead of this both-side simultaneous polishing.

### EXAMPLE

Next, examples of the present invention will be described in detail with comparative examples.

### Examples 1 through 5

First, a plurality of silicon wafers of 200 mm diameter are prepared, and the front and back sides of the silicon wafers are subjected to lapping using the lapping apparatus shown in FIG. 4 as the flattening process. An abrasive material including Al₂O₃ whose count is #1500 is used for the abrasive material in the lapping process, and the silicon wafers are flattened while a flow rate of the abrasive material to be supplied is controlled to be 2.0 L/min, a load of the upper surface table, 70 g/cm²; a rotational frequency of the upper surface table, 10 rpm; and a rotational frequency of the lower surface table, 40 rpm, respectively. Next, as the etching process, the silicon wafers after being flattened are subjected to etching using an etching system shown in FIG. 5. Five types of etchants, in which C₈F₁₇SO₃K (made by MITSUBISHI MATERIALS CORP., brand name; EFTOP EF-102) as a surfactant is mixed into 50 weight percent sodium hydroxide and prepared so as to be 15 g/L (1:100), 1.5 g/L (1:1000), 0.15 g/L (1:10000), 0.015 g/L (1:100000), and 0.0015 g/L (1:1000000 to sodium hydroxide, are used as the etchant. In this etching process, etching is performed while immersing the silicon wafers into the etchant for 15 minutes. The etching removal allowances in this etching are 10 micrometers and 20 micrometers for single side of the wafer and both sides of the wafer, respectively.

### Examples 6 through 10

The flattening process and the etching process are performed in a manner similar to those of the examples 1 through 5 other than replacing the alkaline aqueous solution used for the etchant in the etching process with 40 weight percent aqueous sodium hydroxide solution.

### Comparative Examples 1 through 5

Five types of chemical liquids which consist of only of 50 weight percent aqueous sodium hydroxide solution are prepared as the alkaline aqueous solution, and the flattening process and the etching process are performed in a manner similar those of the example 1 other than using these chemical liquids as the etchant in the etching process as they are. Namely, any fluorochemical surfactant is not added to the etchant.

### Comparative Examples 6 through 10

Five types of chemical liquids which consist of only of 40 weight percent aqueous sodium hydroxide solution are prepared as the alkaline aqueous solution, and the flattening process and the etching process are performed in a manner similar those of the example 1 other than using these chemical liquids as the etchant in the etching process as they are. Namely, any silica powder is not added to the etchant.

### Examples 11 through 20

The flattening process and the etching process are performed in a manner similar to those of the examples 1 through 10 other than performing etching while immersing the silicon wafers into the etchant for 3.5 minutes to 4.5 minutes to set the etching removal allowances in this etching to be 2.5 micrometers for one side of the wafer and 5 micrometers for both sides of the wafer in this etching process.

<Comparative Testing 1>

For the silicon wafers obtained from the examples 1 through 20 and the comparative examples 1 through 10, respectively, the wafer front side roughness is measured using a non-contact front side roughness gauge (made by CHAPMAN company) to calculate Ra and Rmax which are fundamental parameters of wafer surface shapes, respectively. The arithmetic mean roughness Ra which is an amplitude average parameter in a height direction is expressed by an average of absolute values of Z (x) in a reference length as shown in following Equation 1, when the reference length is defined as lr on the wafer surface shown in FIG. 7.

$$\begin{matrix}\text{(Equation 1)} & \\ Ra = \frac{1}{lr} {\int }_{0}^{lr} \vert Z ( x ) \vert d x & ( 1 )\end{matrix}$$

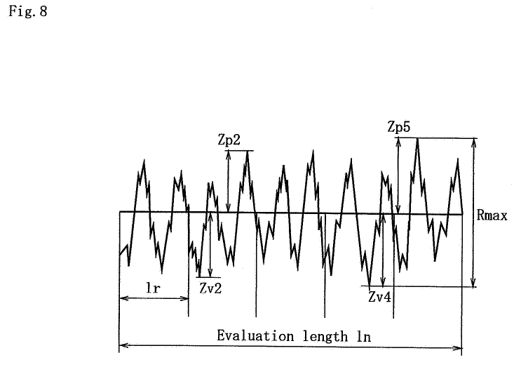

Meanwhile, the maximum cross sectional height Rmax of a roughness curve which is a parameter of a peak and a bottom in the height direction is expressed by a sum of the maximum value of a peak height Zp of an outline curve in an evaluation length ln and the maximum value of the bottom depth Zv, on the wafer surface shown in FIG. 8, as shown in following Equation 2. In FIG. 8, the maximum value of the peak height Zp is Zp₂ and the maximum value of the bottom depth Zv is Zv₄.

(Equation 2)

Rmax=max(Zpi)+max(Zvi) (2)

The results of Ra and Rmax in the silicon wafers obtained from the examples 1 through 20 and the comparative examples 1 through 10 are shown in Table 1 and Table 2, respectively.

TABLE 1

| | | | Alkaline aqueous | | | | | | |
|---|---|---|---|---|---|---|---|---|---|
| | Lapping | | solution | | Fluorochemical | | Etching | Wafer front side | |
| | | Load of upper | | Concentration | surfactant | | removal | roughness | |
| | Polishing | surface table | | (weight | | Addition | allowance | after etching process | |
| | count | (g/cm2) | Type | %) | Type | ratio (g/L) | (micrometer) | Ra [nm] | Rmax [μm] |
| Example 1 | #1500 | 70 | NaOH | 50 | EF102 | 15 | 20 | 180 | 1.71 |
| Example 2 | | | | | | 1.5 | | 183 | 1.74 |
| Example 3 | | | | | | 0.15 | | 185 | 1.77 |
| Example 4 | | | | | | 0.015 | | 190 | 1.81 |
| Example 5 | | | | | | 0.0015 | | 192 | 1.82 |
| Example 6 | #1500 | 70 | NaOH | 40 | EF102 | 15 | 20 | 232 | 2.28 |
| Example 7 | | | | | | 1.5 | | 236 | 2.29 |
| Example 8 | | | | | | 0.15 | | 240 | 2.33 |
| Example 9 | | | | | | 0.015 | | 241 | 2.35 |
| Example 10 | | | | | | 0.0015 | | 248 | 2.37 |
| Comparative | #1500 | 70 | NaOH | 50 | — | — | 20 | 189 | 1.85 |
| example 1 | | | | | | | | | |
| Comparative | | | | | — | — | | 189 | 1.88 |
| example 2 | | | | | | | | | |
| Comparative | | | | | — | — | | 201 | 1.82 |
| example 3 | | | | | | | | | |
| Comparative | | | | | — | — | | 205 | 1.92 |
| example 4 | | | | | | | | | |
| Comparative | | | | | — | — | | 207 | 1.85 |
| example 5 | | | | | | | | | |
| Comparative | #1500 | 70 | NaOH | 40 | — | — | 20 | 258 | 2.43 |
| example 6 | | | | | | | | | |
| Comparative | | | | | — | — | | 267 | 2.44 |
| example 7 | | | | | | | | | |
| Comparative | | | | | — | — | | 251 | 2.51 |
| example 8 | | | | | | | | | |
| Comparative | | | | | — | — | | 263 | 2.55 |
| example 9 | | | | | | | | | |
| Comparative | | | | | — | — | | 265 | 2.51 |
| example 10 | | | | | | | | | |

As is clear from Table 1, when comparing the examples 1 through 10 in which the fluorochemical surfactant is added to the alkaline aqueous solution with the comparative examples 1 through 10 in which the fluorochemical surfactant is not added to the alkaline aqueous solution, it turns out that the results of Ra and Rmax in the examples 1 through 20 are reduced among the wafers to which the flattening process is subjected under similar conditions. According to these results, there is obtained a result that the wafer front side roughness and the wafer flatness are improved, respectively, by using the etchant in which the fluorochemical surfactant is added to the alkaline aqueous solution, allowing reduction in polishing removal allowance in the following both-side simultaneous polishing process. Meanwhile, when comparing the results of the examples 1 through 10 with each other, there is obtained a tendency that the higher the fluorochemical surfactant added to the alkaline aqueous solution is, the further the results of Ra and Rmax decrease, respectively.

TABLE 2

| | | | Alkaline aqueous | | | | | | |
|---|---|---|---|---|---|---|---|---|---|
| | Lapping | | solution | | Fluorochemical | | Etching | Wafer front side | |
| | | Load of upper | | Concentration | surfactant | | removal | roughness | |
| | Polishing | surface table | | (weight | | Addition | allowance | after etching process | |
| | count | (g/cm2) | Type | %) | Type | ratio (g/L) | (micrometer) | Ra [nm] | Rmax [μm] |
| Example 11 | #1500 | 70 | NaOH | 50 | EF102 | 15 | 5 | 0.092 | 0.083 |
| Example 12 | | | | | | 1.5 | | 0.077 | 0.067 |
| Example 13 | | | | | | 0.15 | | 0.067 | 0.050 |
| Example 14 | | | | | | 0.015 | | 0.041 | 0.029 |
| Example 15 | | | | | | 0.0015 | | 0.031 | 0.024 |
| Example 16 | #1500 | 70 | NaOH | 40 | EF102 | 15 | 5 | 0.110 | 0.084 |
| Example 17 | | | | | | 1.5 | | 0.095 | 0.080 |
| Example 18 | | | | | | 0.15 | | 0.080 | 0.064 |
| Example 19 | | | | | | 0.015 | | 0.076 | 0.055 |
| Example 20 | | | | | | 0.0015 | | 0.049 | 0.047 |

As is clearer from Table 2, when comparing the results of the examples 11 through 20 with each other, unlike the above-mentioned Table 1, there is obtained a tendency that the lower the fluorochemical surfactant added to the alkaline aqueous solution is, the further the results of Ra and Rmax decrease, respectively, when a removal allowances by etching is so small as 5 micrometers.

### Examples 21 through 25

First, a plurality of silicon wafers of 200 mm diameter are prepared, and as the flattening process, lapping is subjected to the front and back sides of the silicon wafers in a manner similar to that of the example 1. Subsequently, for the wafers after lapping, finish grinding is subjected to the front side of the silicon wafer using the grinding apparatus shown in FIG. 2 and FIG. 3. As grinding conditions, a grinding count of a grinding stone is set to #2000; a diamond distribution central particle diameter, 3 to 4 micrometers; a rotational frequency of a spindle (wheel), 4800 rpm; a feed speed, 0.3 micrometer/sec; a rotational frequency of the wafer (wafer chuck), 20 rpm; and a processing machining allowance, not more than 10 micrometers. Next, as the etching process, the silicon wafers after being flattened are subjected to etching using an etching system shown in FIG. 5. Five types of etchants, in which C8F17SO3K (made by MITSUBISHI MATERIALS CORP., brand name; EFTOP EF-102) as a surfactant is mixed into 50 weight percent sodium hydroxide and prepared so as to be 15 g/L (1:100), 1.5 g/L (1:1000), 0.15 g/L (1:10000), 0.015 g/L (1:100000), and 0.0015 g/L (1:1000000) to sodium hydroxide, are used as the etchant. In this etching process, etching is performed while immersing the silicon wafers into the etchant for 15 minutes. The etching removal allowances in this etching are 10 micrometers and 20 micrometers for single side of the wafer and both sides of the wafer, respectively.

### Examples 26 through 30

The flattening process and the etching process are performed in a manner similar to those of the examples 21 through 25 other than replacing the alkaline aqueous solution used for the etchant in the etching process with 40 weight percent aqueous sodium hydroxide solution.

### Examples 31 through 35

The flattening process and the etching process are performed in a manner similar to those of the examples 21 through 25 other than replacing the alkaline aqueous solution used for the etchant in the etching process with 30 weight percent aqueous sodium hydroxide solution.

### Examples 36 through 40

The flattening process and the etching process are performed in a manner similar to those of the examples 21 through 25 other than replacing the alkaline aqueous solution used for the etchant in the etching process with 20 weight percent aqueous sodium hydroxide solution.

### Comparative Examples 11 through 15

Five types of chemical liquids which consist of only of 50 weight percent aqueous sodium hydroxide solution are prepared as the alkaline aqueous solution, and the flattening process and the etching process are performed in a manner similar those of the example 21 other than using these chemical liquids as the etchant in the etching process as they are. Namely, any fluorochemical surfactant is not added to the etchant.

### Comparative Examples 16 through 20

Five types of chemical liquids which consist of only of 40 weight percent aqueous sodium hydroxide solution are prepared as the alkaline aqueous solution, and the flattening process and the etching process are performed in a manner similar those of the example 21 other than using these chemical liquids as the etchant in the etching process as they are. Namely, any silica powder is not added to the etchant.

### Comparative Examples 21 through 25

Five types of chemical liquids which consist of only of 30 weight percent aqueous sodium hydroxide solution are prepared as the alkaline aqueous solution, and the flattening process and the etching process are performed in a manner similar those of the example 21 other than using these chemical liquids as the etchant in the etching process as they are. Namely, any fluorochemical surfactant is not added to the etchant.

### Comparative Examples 26 through 30

Five types of chemical liquids which consist of only of 20 weight percent aqueous sodium hydroxide solution are prepared as the alkaline aqueous solution, and the flattening process and the etching process are performed in a manner similar those of the example 21 other than using these chemical liquids as the etchant in the etching process as they are. Namely, any silica powder is not added to the etchant.

### Examples 41 through 60

The flattening process and the etching process are performed in a manner similar to those of the examples 21 through 40 other than performing etching while immersing the silicon wafers into the etchant for 3.5 minutes to 4.5 minutes to set the etching removal allowances in this etching to be 2.5 micrometers for one side of the wafer and 5 micrometers for both sides of the wafer in this etching process.

### Comparative testing 2

For the silicon wafers obtained from the examples 21 through 60 and the comparative examples 11 through 30, respectively, the wafer front side roughness is measured using the non-contact front side roughness gauge (made by CHAPMAN company) in a manner similar to that of the above-mentioned comparative testing 1 to calculate Ra and Rmax which are the fundamental parameters of the wafer front side shapes, respectively. The results of Ra and Rmax in the silicon wafers obtained from the examples 21 through 60 and the comparative examples 11 through 30 are shown in Table 3 through Table 5, respectively.

TABLE 3

| | | | | | | Fluorochemical | | | | |
|---|---|---|---|---|---|---|---|---|---|---|
| | Lapping | | | Alkaline aqueous | | surfactant | | Etching | Wafer front | |
| | | Load of upper | | solution | | | Addition | removal | side roughness | |
| | Polishing | surface table | Finish | | Concentration | | ratio | allowance | after etching process | |
| | count | (g/cm2) | grinding | Type | (weight %) | Type | (g/L) | (micrometer) | Ra [nm] | Rmax [μm] |
| Example | #1500 | 70 | Grinding count | NaOH | 50 | EF102 | 15 | 20 | 125 | 0.27 |
| 21 | | | of a grinding | | | | | | | |
| Example | | | stone | | | | 1.5 | | 128 | 0.28 |
| 22 | | | #2000 | | | | | | | |
| Example | | | Diamond distribution | | | | 0.15 | | 130 | 0.29 |
| 23 | | | central particle | | | | | | | |
| Example | | | diameter | | | | 0.015 | | 134 | 0.31 |
| 24 | | | 3~4 μm | | | | | | | |
| Example | | | | | | | 0.0015 | | 145 | 0.31 |
| 25 | | | | | | | | | | |
| Example | #1500 | 70 | Grinding count | NaOH | 40 | EF102 | 15 | 20 | 215 | 0.49 |
| 26 | | | of a grinding | | | | | | | |
| Example | | | stone | | | | 1.5 | | 223 | 0.52 |
| 27 | | | #2000 | | | | | | | |
| Example | | | Diamond distribution | | | | 0.15 | | 227 | 0.53 |
| 28 | | | central particle | | | | | | | |
| Example | | | diameter | | | | 0.015 | | 239 | 0.53 |
| 29 | | | 3~4 μm | | | | | | | |
| Example | | | | | | | 0.0015 | | 243 | 0.54 |
| 30 | | | | | | | | | | |
| Example | #1500 | 70 | Grinding count | NaOH | 30 | EF102 | 15 | 20 | 287 | 0.58 |
| 31 | | | of a grinding | | | | | | | |
| Example | | | stone | | | | 1.5 | | 300 | 0.58 |
| 32 | | | #2000 | | | | | | | |
| Example | | | Diamond distribution | | | | 0.15 | | 304 | 0.59 |
| 33 | | | central particle | | | | | | | |
| Example | | | diameter | | | | 0.015 | | 307 | 0.60 |
| 34 | | | 3~4 μm | | | | | | | |
| Example | | | | | | | 0.0015 | | 315 | 0.61 |
| 35 | | | | | | | | | | |
| Example | #1500 | 70 | Grinding count | NaOH | 20 | EF102 | 15 | 20 | 458 | 0.76 |
| 36 | | | of a grinding | | | | | | | |
| Example | | | stone | | | | 1.5 | | 469 | 0.77 |
| 37 | | | #2000 | | | | | | | |
| Example | | | Diamond distribution | | | | 0.15 | | 472 | 0.77 |
| 38 | | | central particle | | | | | | | |
| Example | | | diameter | | | | 0.015 | | 482 | 0.78 |
| 39 | | | 3~4 μm | | | | | | | |
| Example | | | | | | | 0.0015 | | 495 | 0.80 |
| 40 | | | | | | | | | | |

TABLE 4

| | | | | | | | | | Wafer | |
|---|---|---|---|---|---|---|---|---|---|---|
| | | | | | | Fluorochemical | | | front side | |
| | Lapping | | | Alkaline aqueous | | surfactant | | Etching | roughness after | |
| | | Load of upper | | solution | | | Addition | removal | etching process | |
| | Polishing | surface table | Finish | | Concentration | | ratio | allowance | | Rmax |
| | count | (g/cm2) | grinding | Type | (weight %) | Type | (g/L) | (micrometer) | Ra [nm] | [μm] |
| Comparative | #1500 | 70 | Grinding count | NaOH | 50 | — | — | 20 | 150 | 0.32 |
| example | | | of a grinding | | | | | | | |
| 11 | | | stone | | | | | | | |
| Comparative | | | #2000 | | | — | — | | 155 | 0.33 |
| example | | | Diamond | | | | | | | |
| 12 | | | distribution | | | | | | | |
| Comparative | | | central particle | | | — | — | | 168 | 0.31 |
| example | | | diameter | | | | | | | |
| 13 | | | 3~4 μm | | | | | | | |
| Comparative | | | | | | — | — | | 157 | 0.30 |
| example | | | | | | | | | | |
| 14 | | | | | | | | | | |
| Comparative | | | | | | — | — | | 155 | 0.35 |
| example | | | | | | | | | | |
| 15 | | | | | | | | | | |
| Comparative | #1500 | 70 | Grinding count | NaOH | 50 | — | — | 20 | 250 | 0.53 |
| example | | | of a grinding | | | | | | | |
| 16 | | | stone | | | | | | | |
| Comparative | | | #2000 | | | — | — | | 255 | 0.54 |
| example | | | Diamond | | | | | | | |
| 17 | | | distribution | | | | | | | |
| Comparative | | | central particle | | | — | — | | 261 | 0.56 |
| example | | | diameter | | | | | | | |
| 18 | | | 3~4 μm | | | | | | | |
| Comparative | | | | | | — | — | | 265 | 0.55 |
| example | | | | | | | | | | |
| 19 | | | | | | | | | | |
| Comparative | | | | | | — | — | | 275 | 0.58 |
| example | | | | | | | | | | |
| 20 | | | | | | | | | | |
| Comparative | #1500 | 70 | Grinding count | NaOH | 30 | — | — | 20 | 325 | 0.61 |
| example | | | of a grinding | | | | | | | |
| 21 | | | stone | | | | | | | |
| Comparative | | | #2000 | | | — | — | | 332 | 0.62 |
| example | | | Diamond | | | | | | | |
| 22 | | | distribution | | | | | | | |
| Comparative | | | central particle | | | — | — | | 321 | 0.61 |
| example | | | diameter | | | | | | | |
| 23 | | | 3~4 μm | | | | | | | |
| Comparative | | | | | | — | — | | 337 | 0.63 |
| example | | | | | | | | | | |
| 24 | | | | | | | | | | |
| Comparative | | | | | | — | — | | 339 | 0.64 |
| example | | | | | | | | | | |
| 25 | | | | | | | | | | |
| Comparative | #1500 | 70 | Grinding count | NaOH | 20 | — | — | 20 | 528 | 0.85 |
| example | | | of a grinding | | | | | | | |
| 26 | | | stone | | | | | | | |
| Comparative | | | #2000 | | | — | — | | 535 | 0.81 |
| example | | | Diamond | | | | | | | |
| 27 | | | distribution | | | | | | | |
| Comparative | | | central particle | | | — | — | | 523 | 0.82 |
| example | | | diameter | | | | | | | |
| 28 | | | 3~4 μm | | | | | | | |
| Comparative | | | | | | — | — | | 529 | 0.81 |
| example | | | | | | | | | | |
| 29 | | | | | | | | | | |
| Comparative | | | | | | — | — | | 532 | 0.83 |
| example | | | | | | | | | | |
| 30 | | | | | | | | | | |

As is clearer from Table 3 and Table 4, when comparing the examples 21 through 40 in which the fluorochemical surfactant is added to the alkaline aqueous solution with the comparative examples 11 through 30 in which the fluorochemical surfactant is not added to the alkaline aqueous solution, it turns out that the results of Ra and Rmax of the examples 21 through 40 decrease, respectively. According to this result, there is obtained a result that the wafer front side roughness and the wafer flatness are improved, respectively, by using the etchant in which the fluorochemical surfactant is added to the alkaline aqueous solution, allowing a reduction in polishing removal allowance in the following both-side simultaneous polishing process. Meanwhile, when comparing the results of the examples 21 through 40 with each other, there is obtained a tendency that the higher the fluorochemical surfactant added to the alkaline aqueous solution is, the further the results of Ra and Rmax decrease, respectively.

TABLE 5

| | | | | | | | | | Wafer | |
|---|---|---|---|---|---|---|---|---|---|---|
| | | | | | | Fluorochemical | | | front side | |
| | Lapping | | | Alkaline aqueous | | surfactant | | Etching | roughness after | |
| | | Load of upper | | solution | | | Addition | removal | etching process | |
| | Polishing | surface table | | | Concentration | | ratio | allowance | | Rmax |
| | count | (g/cm2) | Finish grinding | Type | (weight %) | Type | (g/L) | (micrometer) | Ra [nm] | [μm] |
| Example | #1500 | 70 | Grinding count | NaOH | 50 | EF102 | 15 | 5 | 0.204 | 0.161 |
| 41 | | | of a grinding | | | | | | | |
| Example | | | stone | | | | 1.5 | | 0.185 | 0.130 |
| 42 | | | #2000 | | | | | | | |
| Example | | | Diamond | | | | 0.15 | | 0.175 | 0.099 |
| 43 | | | distribution | | | | | | | |
| Example | | | central particle | | | | 0.015 | | 0.146 | 0.037 |
| 44 | | | diameter | | | | | | | |
| Example | | | 3~4 μm | | | | 0.0015 | | 0.076 | 0.037 |
| 45 | | | | | | | | | | |
| Example | #1500 | 70 | Grinding count | NaOH | 40 | EF102 | 15 | 5 | 0.177 | 0.112 |
| 46 | | | of a grinding | | | | | | | |
| Example | | | stone | | | | 1.5 | | 0.146 | 0.058 |
| 47 | | | #2000 | | | | | | | |
| Example | | | Diamond | | | | 0.15 | | 0.131 | 0.040 |
| 48 | | | distribution | | | | | | | |
| Example | | | central particle | | | | 0.015 | | 0.085 | 0.040 |
| 49 | | | diameter | | | | | | | |
| Example | | | 3~4 μm | | | | 0.0015 | | 0.070 | 0.022 |
| 50 | | | | | | | | | | |
| Example | #1500 | 70 | Grinding count | NaOH | 30 | EF102 | 15 | 5 | 0.132 | 0.068 |
| 51 | | | of a grinding | | | | | | | |
| Example | | | stone | | | | 1.5 | | 0.093 | 0.068 |
| 52 | | | #2000 | | | | | | | |
| Example | | | Diamond | | | | 0.15 | | 0.081 | 0.051 |
| 53 | | | distribution | | | | | | | |
| Example | | | central particle | | | | 0.015 | | 0.072 | 0.035 |
| 54 | | | diameter | | | | | | | |
| Example | | | 3~4 μm | | | | 0.0015 | | 0.048 | 0.019 |
| 55 | | | | | | | | | | |
| Example | #1500 | 70 | Grinding count | NaOH | 20 | EF102 | 15 | 5 | 0.135 | 0.078 |
| 56 | | | of a grinding | | | | | | | |
| Example | | | stone | | | | 1.5 | | 0.114 | 0.066 |
| 57 | | | #2000 | | | | | | | |
| Example | | | Diamond | | | | 0.15 | | 0.108 | 0.066 |
| 58 | | | distribution | | | | | | | |
| Example | | | central particle | | | | 0.015 | | 0.090 | 0.053 |
| 59 | | | diameter | | | | | | | |
| Example | | | 3~4 μm | | | | 0.0015 | | 0.065 | 0.029 |
| 60 | | | | | | | | | | |

As is clear from Table 5, when comparing the results of the examples 41 through 60 with each other, unlike the above-mentioned Table 3, there is obtained a tendency that the lower the fluorochemical surfactant added to the alkaline aqueous solution is, the further the results of Ra and Rmax decrease, respectively, when the removal allowances by etching is so small as 5 micrometers.

What is claimed is:

1. An etchant for controlling a silicon wafer surface shape, wherein a fluorochemical surfactant is uniformly mixed in an alkaline aqueous solution.

2. The etchant according to claim 1, wherein the alkaline aqueous solution is an aqueous sodium hydroxide solution of 20-50 weight percent, and an addition ratio of the fluorochemical surfactant to be added to the alkaline aqueous solution is 0.0015-15 g/L to sodium hydroxide.

3. A method for manufacturing silicon wafers, comprising the sequential steps of:
a flattening step comprising grinding or lapping front and back sides of a thin disc-shaped silicon wafer obtained by slicing a silicon single crystal ingot;
an etching step comprising immersing the silicon wafer in an etchant obtained by mixing a fluorochemical surfactant uniformly in an alkaline aqueous solution to thereby etch the front and back sides of the silicon wafer; and
a both-side simultaneous polishing step comprising simultaneously polishing the front and back sides of the etched silicon wafer.

4. The method according to claim 3, wherein the alkaline aqueous solution is an aqueous sodium hydroxide solution of 20-50 weight percent, and an addition ratio of the fluorochemical surfactant to be added to the alkaline aqueous solution is 0.0015-15 g/L to sodium hydroxide.

5. A method for manufacturing silicon wafers, comprising the sequential steps of:
a flattening step comprising grinding or lapping front and back sides of a thin disc-shaped silicon wafer obtained by slicing a silicon single crystal ingot;
an etching step comprising immersing the silicon wafer in an etchant obtained by mixing a fluorochemical surfactant uniformly in an alkaline aqueous solution to thereby etch the front and back sides of the silicon wafer;
and a single-side polishing step comprising polishing the front and backsides of the etched silicon wafer for every side.

6. The method according to claim 4, wherein the alkaline aqueous solution is an aqueous sodium hydroxide solution of 20-50 weight percent, and an addition ratio of the fluorochemical surfactant to be added to the alkaline aqueous solution is 0.0015-15 g/L to sodium hydroxide.

7. The etchant of claim 1 wherein the fluorochemical surfactant is selected from the group consisting of 1,1,2,2,3,3,4,4,5,5,6,6,7,7,8,8,8-pentadecafluoro-1-octanesulfonic acid (C₈F₁₇SO₃H), Potassium perfluoro octanesulfonate (C₈F₁₇SO₃K) Sodium perfluoro octanesulfonate (C₈F₁₇SO₃Na) Ammonium perfluoro octanesulfonate (C₈F₁₇SO₃NH₄), Lithium perfluoro octanesulfonate (C₈F₁₇SO₃Li) Potassium N-[(perfluorooctyl) sulfonyl]-N-propylglycinate (C₈F₁₇SO₂N(C₃H₇)CH₂COOK), N-(2-hydroxylethyl)-N-propyl perfluorooctane sulfonamide (C₈F₁₇SO₂N(C₃H₇)CH₂CH₂OH), N-polyoxyethylene-N-propyl perfluorooctane sulfonamide (C₈F₁₇SO₂N(C₃H₇) (C₂H₄O)ₙH, wherein n=3, 10, or 20, Phosphorous acid ester ([C₈F₁₇SO₂N(C₃H₇) (C₂H₄O)]₂PO(OH)), Phosphorous acid ester ammonium salt ([C₈F₁₇SO₂N(C₃H₇) (C₂H₄O)]₂PO(ONH₄)), N-[3-(perfluorooctanesulfonamide)propyl]-N,N,N-trimethylammonium iodide (C₈F₁₇SO₂NHCH₂CH₂CH₂N+(CH₃)₃I⁻), Acrylic acid polyoxyalkylene alkyl ether acrylic acid N-perfluoro octyl sulformyl-N-alkyl amino ethyl copolymer Acrylic acid polyoxyalkylene glycolmonoester acrylic acid N-perfluoro octyl sulformyl-N-alkyl amino ethyl copolymer Acrylic acid polyoxyethylene alkyl ether acrylic acid N-perfluoro octyl sulformyl-N-alkyl aminoethyl interpolymerization thing (50% ethyl acetate), Acrylic acid polyoxyalkylene alkyl ether acrylic acid N-perfluoro octyl sulformyl-N-alkyl amino ethyl copolymer (50% ethyl acetate), Acrylic acid polyoxyalkylene glycolmonoester acrylic acid N-perfluoro octyl sulformyl-N-alkyl amino ethyl copolymer Pentadecafluorooctanoic acid (C₇F₁₅COOH), Pentadecafluorooctanoic acid ammonium (C₇F₁₅COONH₄), Perfluoro butanesulfonate (C₄F₉SO₃H), Potassium perfluoro butanesulfonate (C₄F₉SO₃K) and Lithium perfluoro butanesulfonate (C₄F₉SO₃Li).

8. The etchant of claim 1 wherein the fluorochemical surfactant is selected from the group consisting of C₈F₁₇SO₃K and C₈F₁₇SO₃Na.

9. The method of claim 3 wherein the wherein the fluorochemical surfactant is selected from the group consisting of 1,1,2,2,3,3,4,4,5,5,6,6,7,7,8,8,8-pentadecafluoro-1-octanesulfonic acid (C₈F₁₇SO₃H), Potassium perfluoro octanesulfonate (C₈F₁₇SO₃K) Sodium perfluoro octanesulfonate (C₈F₁₇SO₃Na) Ammonium perfluoro octanesulfonate (C₈F₁₇SO₃NH₄), Lithium perfluoro octanesulfonate (C₈F₁₇SO₃Li) Potassium N—[(perfluorooctyl) sulfonyl]-N-propylglycinate (C₈F₁₇SO₂N(C₃H₇)CH₂COOK), N-(2-hydroxylethyl)-N-propyl perfluorooctane sulfonamide (C₈F₁₇SO₂N(C₃H₇)CH₂CH₂OH), N-polyoxyethylene-N-propyl perfluorooctane sulfonamide (C₈F₁₇SO₂N(C₃H₇)(C₂H₄O)ₙH, wherein n=3, 10, or 20, Phosphorous acid ester ([C₈F₁₇SO₂N(C₃H₇) (C₂H₄O)]₂PO(OH)), Phosphorous acid ester ammonium salt ([C₈F₁₇SO₂N(C₃H₇) (C₂H₄O)]₂PO(ONH₄)), N-[3-(perfluorooctanesulfonamide)propyl]-N,N,N-trimethylammonium iodide (C₈F₁₇SO₂NHCH₂CH₂CH₂N+(CH₃)₃I⁻), Acrylic acid polyoxyalkylene alkyl ether acrylic acid N-perfluoro octyl sulformyl-N-alkyl amino ethyl copolymer, Acrylic acid polyoxyalkylene glycolmonoester acrylic acid N-perfluoro octyl sulformyl-N-alkyl amino ethyl copolymer Acrylic acid polyoxyethylene alkyl ether acrylic acid N-perfluoro octyl sulformyl-N-alkyl aminoethyl copolymer (50% ethyl acetate), Acrylic acid polyoxyalkylene alkyl ether acrylic acid N-perfluoro octyl sulformyl-N-alkyl amino ethyl copolymer (50% ethyl acetate), Acrylic acid polyoxyalkylene glycolmonoester acrylic acid N-perfluoro octyl sulformyl-N-alkyl amino ethyl copolymer Pentadecafluorooctanoic acid (C₇F₁₅COOH), Pentadecafluorooctanoic acid ammonium (C₇F₁₅COONH₄), Perfluoro butanesulfonate (C₄F₉SO₃H), Potassium perfluoro butanesulfonate (C₄F₉SO₃K), and Lithium perfluoro butanesulfonate (C₄F₉SO₃Li).

10. The method of claim 3 wherein the fluorochemical surfactant is selected from the group consisting of C₈F₁₇SO₃K and C₈F₁₇SO₃Na.

11. The method of claim 5 wherein the wherein the fluorochemical surfactant is selected from the group consisting of 1,1,2,2,3,3,4,4,5,5,6,6,7,7,8,8,8-pentadecafluoro-1-octanesulfonic acid (C₈F₁₇SO₃H), Potassium perfluoro octanesulfonate (C₈F₁₇SO₃K) Sodium perfluoro octanesulfonate (C₈F₁₇SO₃Na) Ammonium perfluoro octanesulfonate (C₈F₁₇SO₃NH₄), Lithium perfluoro octanesulfonate (C₈F₁₇SO₃Li) Potassium N-[(perfluorooctyl) sulfonyl]-N-propylglycinate (C₈F₁₇SO₂N(C₃H₇)CH₂COOK), N-(2-hydroxylethyl)-N-propyl perfluorooctane sulfonamide (C₈F₁₇SO₂N(C₃H₇)CH₂CH₂OH), N-polyoxyethylene-N-propyl perfluorooctane sulfonamide (C₈F₁₇SO₂N(C₃H₇) (C₂H₄O)ₙH, wherein n=3, 10, or 20, Phosphorous acid ester ([C₈F₁₇SO₂N(C₃H₇) (C₂H₄O)]₂PO(OH), Phosphorous acid ester ammonium salt ([C₈F₁₇SO₂N(C₃H₇) (C₂H₄O)]₂PO(ONH₄)), N-[3-(perfluorooctanesulfonamide)propyl]-N,N,N-trimethylammonium iodide (C₈F₁₇SO₂NHCH₂CH₂CH₂N+(CH₃)₃I⁻), Acrylic acid polyoxyalkylene alkyl ether acrylic acid N-perfluoro octyl sulformyl-N-alkyl amino ethyl copolymer, Acrylic acid polyoxyalkylene glycolmonoester acrylic acid N-perfluoro octyl sulformyl-N-alkyl amino ethyl copolymer Acrylic acid polyoxyethylene alkyl ether acrylic acid N-perfluoro octyl sulformyl-N-alkyl aminoethyl copolymer (50% ethyl acetate), Acrylic acid polyoxyalkylene alkyl ether acrylic acid N-perfluoro octyl sulformyl-N-alkyl amino ethyl copolymer (50% ethyl acetate), Acrylic acid polyoxyalkylene glycolmonoester acrylic acid N-perfluoro octyl sulformyl-N-alkyl amino ethyl copolymer Pentadecafluorooctanoic acid (C₇F₁₅COOH), Pentadecafluorooctanoic acid ammonium (C₇F₁₅COONH₄), Perfluoro butanesulfonate (C₄F₉SO₃H), Potassium perfluoro butanesulfonate (C₄F₉SO₃K), and Lithium perfluoro butanesulfonate (C₄F₉SO₃Li).

12. The method of claim 5 wherein the fluorochemical surfactant is selected from the group consisting of C₈F₁₇SO₃K and C₈F₁₇SO₃Na.
